(19) United States
(12) Patent Application Publication
(10) Pub. No.: US 2022/0207202 A1
(43) Pub. Date: Jun. 30, 2022

(54) Systems And Methods To Generate A Floorplan Of A Building

(71) Applicant: OPAL AI Inc., Los Angeles, CA (US)

(72) Inventors: Pooriya Beyhaghi, San Diego, CA (US); Keyvan Noury, Los Angeles, CA (US); Shahrouz Ryan Alimo, Los Angeles, CA (US)

(21) Appl. No.: 17/564,300

(22) Filed: Dec. 29, 2021

Related U.S. Application Data
(60) Provisional application No. 63/131,531, filed on Dec. 29, 2020.

(51) Int. Cl. G06F 30/13; G06T 17/20; G06F 30/23; G06N 20/00; G06F 30/12

(52) U.S. Cl. CPC G06F 30/13; G06T 17/20; G06F 30/12; G06N 20/00; G06F 30/23

(57) ABSTRACT

The disclosure generally pertains to generating floorplans. An example method to do so involves generating a three-dimensional polygonal mesh representation of at least a portion of a building (one floor of the building, for example). The three-dimensional polygonal mesh representation is generated from images captured by a smartphone, for example. The processor evaluates the three-dimensional polygonal mesh representation for identifying a room, and for determining an authenticity of an element included in the three-dimensional polygonal mesh representation (a corner or an edge of a wall, for example). The authenticity may be determined in various ways such as by executing a corner likelihood procedure, an edge likelihood procedure, or a simulation procedure. Based on the authenticity of the element, a structure that is associated with the element (a wall, for example) is included in a rendering of the room (a floorplan, for example).

### CROSS-REFERENCE TO RELATED APPLICATION

This application claims priority to and the benefit of U.S. Provisional Patent Application No. 61/131,531, filed Dec. 29, 2020, the entire disclosure of which is hereby incorporated by reference.

### BACKGROUND

A floorplan of a building can be used for various purposes such as, for example, to provide information about a layout and a size of a house, to provide information about a layout and a size of a commercial building (office, warehouse, store, hospital, etc.), to display information about emergency exits on a floor (doors, stairs, etc.), and for purposes of construction or remodeling.

One method to generate a floorplan of an existing structure (a house, an office, a store, a warehouse, etc.) involves a surveyor walking from one room to another and drawing a sketch of each room (a rectangular box outline of a room, for example). The sketch may then be updated by adding dimensional measurements (length, width, height, etc.) obtained by use of a handheld measuring device (a measuring tape, a laser measurement tool, etc.). Annotated notes may be added to provide additional information such as, for example, a location, size, and shape of a door or a window. The sketches may then be forwarded to a draftsman for producing a blueprint of the floorplan. In some cases, the blueprint may be a paper document and in some other cases, the blueprint may be produced in the form of a computer-aided design (CAD) drawing.

Preparing a floorplan in this manner has several handicaps. A first handicap pertains to an amount of manual labor involved in the documenting procedure (sketching, measuring, annotating, etc.). A second handicap pertains to costs such as surveyor fees and drafting fees. A third disadvantage pertains to an amount of time involved in performing the procedure (surveying, drafting, etc.).

It is therefore desirable to provide a solution that addresses such handicaps.

### SUMMARY

In a first example embodiment in accordance with the disclosure, a method includes generating a three-dimensional polygonal mesh representation of at least a portion of a first building; identifying, in the three-dimensional polygonal mesh representation, a first room; determining an authenticity of an element indicated in the three-dimensional polygonal mesh representation; and one of including a structure or excluding the structure in a rendering of the first room, based on the authenticity of the element indicated in the three-dimensional polygonal mesh representation.

In general, the first example embodiment is directed at a method to generate a rendering of a building (a room of the building or a floor of the building, for example) and involves generating a three-dimensional polygonal mesh representation of at least a portion of the building. The three-dimensional polygonal mesh representation is created from images captured by, for example, a smartphone. A room is identified in the three-dimensional polygonal mesh representation. The authenticity of an element indicated in the three-dimensional polygonal mesh representation is then determined. The element indicated in the three-dimensional polygonal mesh representation may correspond to an edge of a wall or a corner of the room that may or may not exist. The authenticity may be determined in various ways such as, for example, by executing a corner likelihood procedure, an edge likelihood procedure, a simulation procedure, and/or a three-dimensional polygonal mesh representation comparison procedure. Based on the authenticity of the element indicated in the three-dimensional polygonal mesh representation, a structure such as, for example, a wall or a corner, may either be included or excluded in a rendering of the room (a floorplan, for example).

In a second example embodiment in accordance with the disclosure, a method includes generating a three-dimensional polygonal mesh representation of at least a portion of a first building; generating a reconstructed floorplan by operating upon the three-dimensional polygonal mesh representation, refining the reconstructed floorplan by comparing the reconstructed floorplan to a reference floorplan; and producing a rendered floorplan based on refining the reconstructed floorplan.

In general, the second example embodiment is directed at a method to generate a rendering of a building (a room of the building or a floor of the building, for example) involves using a smartphone, for example, to capture one or more images and generating a three-dimensional polygonal mesh representation of at least a portion of the building. The three-dimensional polygonal mesh representation may be operated upon to generate a reconstructed floorplan. The reconstructed floorplan is refined by comparing the reconstructed floorplan to a reference floorplan. The reference floorplan can be a simulated floorplan or a floorplan of another building. The refined floorplan may then be used to produce a rendering of the floorplan (a blue print, for example).

In a third example embodiment in accordance with the disclosure, a floorplan generating device includes a processor and a memory containing computer-executable instructions. The processor is configured to access the memory and execute the computer-executable instructions to perform operations that include generating a three-dimensional polygonal mesh representation of at least a portion of a first building; identifying, in the three-dimensional polygonal mesh representation, a first room; determining an authenticity of an element indicated in the three-dimensional polygonal mesh representation corresponding to the first room; and either including a structure or excluding the structure in a rendering of the first room, based on the authenticity of the element indicated in the three-dimensional polygonal mesh representation.

Further aspects of the disclosure are shown in the specification, drawings, and claims below.

### BRIEF DESCRIPTION OF THE DRAWINGS

Many aspects of the invention can be better understood with reference to the following drawings. The components in the drawings are not necessarily to scale. Instead, emphasis is placed upon clearly illustrating the principles of the invention. Moreover, in the drawings, like reference numerals designate corresponding parts, or descriptively similar parts, throughout the several views and embodiments.

FIG. 1 shows an example implementation of a floorplan generation system in accordance with an embodiment of the disclosure.

FIG. 2 illustrates an example image capture procedure in accordance with the disclosure.

FIG. 3 illustrates an example image that may be captured by a personal device in accordance with the disclosure.

FIG. 4 illustrates an example framework that may be operated upon by a computer for generating a 3D rendering of a floor of a building in accordance with the disclosure.

FIG. 5 illustrates an example 3D rendering of a floor of a building in accordance with the disclosure.

FIG. 6 shows an example floorplan in accordance with the disclosure.

FIG. 7 shows a block diagram of a method to generate a floorplan in accordance with an embodiment of the disclosure.

FIG. 8 illustrates a first example cross-sectional view of a three-dimensional polygonal mesh representation that may be used for generating a floorplan in accordance with the disclosure.

FIG. 9 illustrates a second example cross-sectional view that is a modified version of the cross-sectional view shown in FIG. 8.

FIG. 10 illustrates a third example cross-sectional view that is a modified version of the cross-sectional view shown in FIG. 9.

FIG. 11 illustrates a fourth example cross-sectional view of a three-dimensional polygonal mesh representation that may be used for generating a floorplan in accordance with the disclosure.

FIG. 12 illustrates a fifth example cross-sectional that is a modified version of the cross-sectional view shown in FIG. 11.

FIG. 13 illustrates a sixth example cross-sectional that is a modified version of the cross-sectional view shown in FIG. 12.

FIG. 14 shows a likelihood diagram that illustrates the likelihood of various corners being present in a Manhattan layout.

FIG. 15 shows a likelihood diagram that illustrates the likelihood of various edges being present in a Manhattan layout.

FIG. 16 shows a likelihood diagram that illustrates the likelihood of various corners being present in a non-Manhattan layout.

FIG. 17 shows a likelihood diagram that illustrates the likelihood of various edges being present in a non-Manhattan layout.

FIG. 18 illustrates an individual executing a floorplan generation procedure upon a computer in accordance with an embodiment of the disclosure.

FIG. 19 shows some example components that may be provided in a floorplan generating device in accordance with an embodiment of the disclosure.

### DETAILED DESCRIPTION

Throughout this description, embodiments and variations are described for the purpose of illustrating uses and implementations of the inventive concept. The illustrative description should be understood as presenting examples of the inventive concept, rather than as limiting the scope of the concept as disclosed herein. For example, it must be understood that various words, labels, and phrases are used herein for description purposes and should not be interpreted in a limiting manner.

For example, it must be understood that the word “floor” as used herein is not limited to the entire floor but is equally pertinent to a portion of a floor (one or more rooms, for example). The label “3D” as used herein is a shortened version of the phrase “three-dimensional.” The word “floorplan” as used herein encompasses a “floor map” which may be generally understood as a birds-eye view of the layout of a building. A “floorplan” can include details such as, dimensions, scaling, for example whereas a “floor map” may not include such details. It must also be understood that subject matter described herein with reference to the word “floorplan” is equally applicable to items that may be referred to in the art by terminology such as, for example, “measured drawing,” “record drawing,” and “as-built drawing.” The word “rendering” as used herein encompasses various types of pictorial diagrams produced by a computer and particularly encompasses items such as a floorplan, a three-dimensional drawing, an isometric view of a building, and a birds-eye view of a building.

The word “example” as used herein is intended to be non-exclusionary and non-limiting in nature. One of ordinary skill in the art will understand the principles described herein and recognize that these principles can be applied to a wide variety of applications and situations, using a wide variety of tools, processes, and physical elements.

Words such as “implementation,” “scenario,” “case,” “approach,” and “situation” must be interpreted in a broad context, and it must be understood that each such word represents an abbreviated version of the phrase “In an example “xxx” in accordance with the disclosure” (where “xxx” corresponds to “implementation,” “application,” “scenario,” “case,” “situation” etc.).

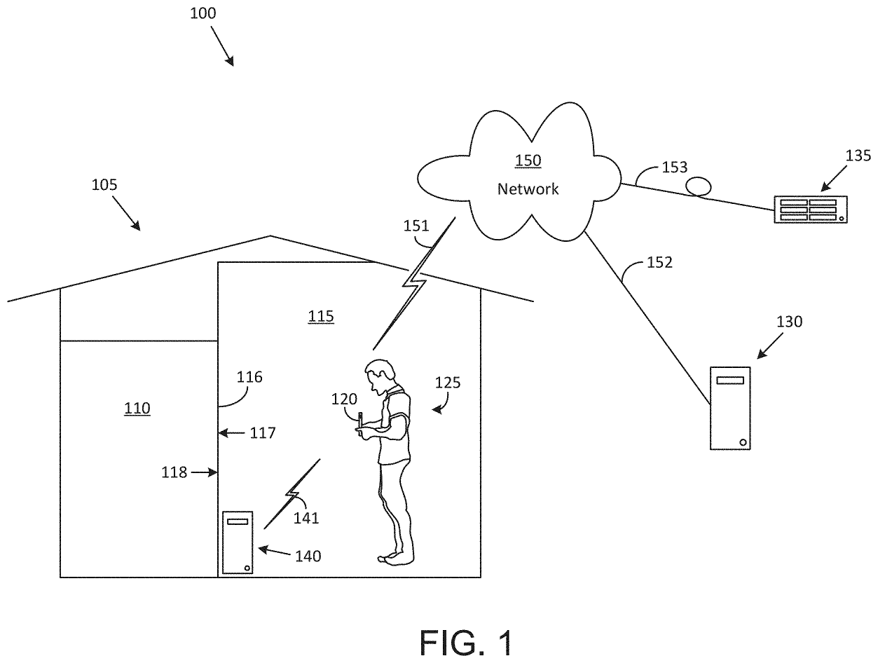

FIG. 1 shows an example implementation of a floorplan generation system 100 in accordance with an embodiment of the disclosure. In the example configuration shown in FIG. 1, the floorplan generation system 100 has a distributed architecture where various components of the floorplan generation system 100 are provided in various example devices. The example devices include a personal device 120 carried by an individual 125, a computer 130, a cloud storage device 135, and a computer 140. In another example configuration, the floorplan generation system 100 may be wholly contained in a single device such as, for example, in the personal device 120 or in the computer 130.

The floorplan generation system 100 may be used to generate a floorplan of a floor of a building 105. The building 105 in this example scenario is a residential building having a single floor. In other scenarios, the building 105 can be any of various types of buildings having one or more floors, such as, for example, a warehouse, an office building, a store, a hospital, a school, or a multi-storied residential building.

The various devices shown in FIG. 1 are communicatively coupled to each other via a network 150. The network 150, which can be any of various types of networks such as, for example, a wide area network (WAN), a local area network (LAN), a public network, and/or a private network, may include various types of communication links (a wired communication link, a wireless communication link, an optical communication link, etc.) and may support one or more of various types of communication protocols (Transmission Control Protocol (TCP), Internet Protocol (IP), Ethernet, Post Office Protocol (POP), Simple Mail Transfer Protocol (SMT), File Transfer Protocol (FTP), Hyper Text Transfer Protocol (HTTP), and Hyper Text Transfer Protocol Secure (HTTPS), etc.)

In the illustrated scenario, the computer 130 is coupled to the network 150 via a wired link 152, the cloud storage device 135 is coupled to the network 150 via an optical link 153, and the personal device 120 is coupled to the network 150 via a wireless link 151.

The computer 130 can be any of various types of devices such as, for example, a personal computer, a desktop computer, or a laptop computer. In some scenarios, the computer may be configured to operate as a server computer or a client computer. More particularly, the computer 130 (and the personal device 120) can include a processor and a memory containing computer-executable instructions. The processor is configured to access the memory and execute the computer-executable instructions to perform various operations in accordance with the disclosure.

The cloud storage device 135 may be used for storing various types of information such as, for example, a database containing images and/or floorplans of various buildings.

The computer 140 can be any of various types of devices such as, for example, a personal computer, a desktop computer, or a laptop computer. The computer 140 includes a processor and a memory containing computer-executable instructions. The processor is configured to access the memory and execute the computer-executable instructions to perform various operations in accordance with the disclosure. In the illustrated example scenario, the computer 140 is communicatively coupled to the personal device 120 via a wireless link 141. The wireless link 141 may be configured to support wireless signal formats such as, for example, WiFi, Bluetooth®, near-field communications (NFC), microwave communications, optical communications, and/or cellular communications.

The personal device 120 can be any of various types of devices that include a camera. A non-exhaustive list of personal devices can include a smartphone, a tablet computer, a phablet (phone plus tablet), a laptop computer, and a wearable device (a smartwatch, for example). In the illustrated scenario, the personal device 120 is a hand-held device that is used by the individual 125 for capturing images of a room 115 and a room 110 located on a ground floor of the building 105. The images may be captured in various forms such as, for example, in the form of one or more digital images, a video clip, or a real-time video stream. The individual 125 may swivel the personal device 120 in various directions for capturing images of various objects (furniture, wall fixtures, wall hangings, floor coverings, etc.) and structural elements (walls, corners, ceiling, floor, doors, windows, etc.) of the room 115.

In one case, the individual 125 remains stationary at a first location (a central area of the room 115, for example) and points the personal device 120 in various directions for capturing a set of images. The individual 125 may then move to various other locations in the room 115 and repeat the image capture procedure. In another case, the individual 125 may capture images in the form of a real-time video stream (or a set of video clips) as the individual 125 moves around the room 115. The various images can include an image of a surface 117 of a wall 116 in the room 115.

The individual 125 may then move into the room 110 which is adjacent to the room 115, and repeat the image capture procedure. In this example, the room 110 shares the wall 116 with the room 115, and the images captured in the room 110 can include an image of a surface 118 of the wall 116. An example challenge associated with generating a floorplan of the ground floor of the building 105 is to recognize that the surface 118 and the surface 117 belong to a wall that is shared in common between the room 115 and the room 110 (in this case, the wall 116).

In an example implementation, the personal device 120 includes a light detection and ranging (LiDAR) component that uses a laser beam to obtain distance information between a camera of the personal device 120 and imaging targets (in this case, the various objects and structural elements of the room 115 and the room 110). Digital images captured by the personal device 120, and more particularly, pixels of each digital image captured by the personal device 120, can include distance information as well as various other types of information (scale, angles, time, camera settings, etc.). This information, which can be provided in the form of image metadata, can be used to convert a digital image into various formats. In an example implementation, each digital image can be converted into a three-dimensional polygonal mesh representation of an imaging target.

In a first example implementation, the personal device 120 can include a software application that operates upon the images captured by the personal device 120 and generates a floorplan of the ground floor of the building 105 in accordance with the disclosure. The floorplan can be made available to the individual 125 and/or other individuals for various purposes.

In a second example implementation, the images captured by the personal device 120 and/or the three-dimensional polygonal mesh representations of the images may be transferred to the computer 130 via the network 150. The computer 130 can operate upon the images and/or the three-dimensional polygonal mesh representations for generating a floorplan of the ground floor of the building 105 in accordance with the disclosure.

In a third example implementation, the images captured by the personal device 120 and/or the three-dimensional polygonal mesh representations of the images may be transferred to the computer 140 via the wireless link 141. The computer 140 can operate upon the images, and/or the three-dimensional polygonal mesh representations, for generating a floorplan of the ground floor of the building 105 in accordance with the disclosure.

In a fourth example implementation, the images captured by the personal device 120 and/or the three-dimensional polygonal mesh representations of the images, may be transferred to the cloud storage device 135. The cloud storage device 135 may be accessed by one or more computers (such as, for example, the computer 130) for retrieval of the images and/or the three-dimensional polygonal mesh representations for generating a floorplan of the ground floor of the building 105 in accordance with the disclosure.

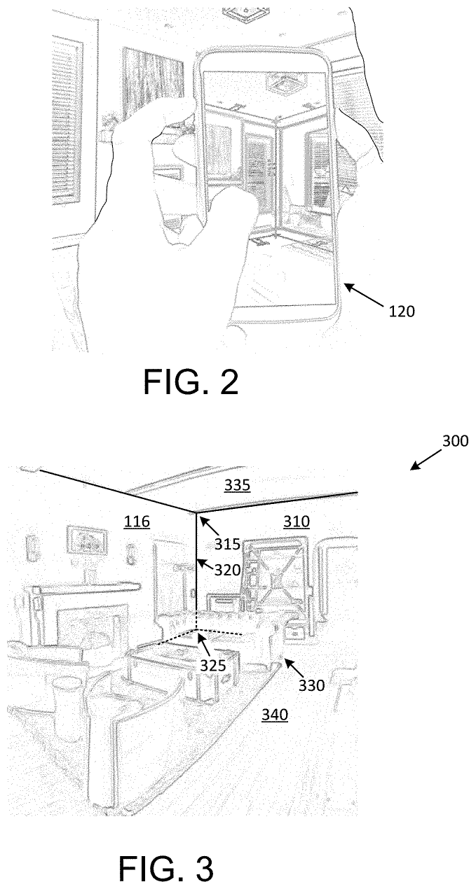

FIG. 2 illustrates an example image capture procedure in accordance with the disclosure. The example procedure can be executed by use of the personal device 120. In this case, the image being captured by the personal device 120 corresponds to one view of the room 115. Additional images corresponding to other views of the room 115 may be captured and all the images (and/or three-dimensional polygonal mesh representations) may be combined to provide a comprehensive view of the room 115 in the form of a three-dimensional polygonal mesh representation, for example. The comprehensive view of the room 115 may then be combined with comprehensive views of other rooms such as, for example, the room 110. The combining procedure can be executed by a processor of the personal device 120 and/or a computer such as, for example, the computer 130. The combining procedure can be followed by a floorplan generation procedure for generating a floorplan of the ground floor of the building 105. Floorplans of other floors (in the case of a multi-storied building) can be generated in a similar manner.

FIG. 3 illustrates an example image 300 that may be captured by the personal device 120 in accordance with the disclosure. The image 300 corresponds to one view of the room 115. The view encompasses various objects and structural elements of the room 115. The various objects include various pieces of furniture (such as, for example, a sofa 330), wall hangings, wall fixtures, and floor coverings (an area rug, for example). The room 115 includes various structures such as, for example, walls, windows, doors, and a fireplace. The walls include structural components such as, for example, an edge 320, a corner 315, and a corner 325.

The edge 320 corresponds to a vertical joint formed by the wall 116 and a wall 310. The vertical joint extends from the floor 340 to the ceiling 335 of the room 115 and includes a corner 315 and a corner 325. The corner 315 exists at a confluence location where the wall 116 and the wall 310 meet the ceiling 335. The corner 325 exists at a confluence location where the wall 116 and the wall 310 meet the floor 340.

The corner 325 and a portion of the edge 320 are obscured by the sofa 330. Evaluation of the image 300 by a human may allow the human to make an assumption that the edge 320 extends down to the floor 340, and that the corner 325 is formed at the confluence of the wall 116, the wall 310, and the floor 340. However, in some scenarios, the assumption may be erroneous, such as, for example, when the edge 320 extends non-linearly and terminates above the floor 340 (at a ledge, for example). The non-linear edge and the ledge are obscured by the sofa 330 in the image 300.

A computer, such as, for example, the computer 130, may evaluate a three-dimensional polygonal mesh representation of the room 115. The three-dimensional polygonal mesh representation can include a first element (a line, for example) corresponding to the edge 320 and a second element (a dot, for example) corresponding to the corner 325. As indicated above, the corner 325 and a portion of the edge 320 (the portion obscured by the sofa 330) may or may not exist in the room 115. Consequently, the computer has to evaluate the three-dimensional polygonal mesh representation to determine an authenticity of the first element (the line) and/or the second element (the dot) included in the three-dimensional polygonal mesh representation. If the first element (the line) is authentic, the computer may generate a rendering (a floorplan, for example) that includes the portion of the edge 320 obscured by the sofa 330. Conversely, if the first element (the line) is merely an aberration or artifact, the computer may generate a rendering (a floorplan, for example) that excludes the portion of the edge 320 obscured by the sofa 330. The corner 325 may be similarly included or excluded in the rendering by the computer based on authenticity. Objects such as furniture, wall hangings, wall fixtures, and floor coverings are typically excluded in the rendering.

In an example implementation in accordance with the disclosure, the computer 130 may make evaluate the three-dimensional polygonal mesh representation of the room 115 (and other rooms in the building 105) by executing a software program that utilizes one or more procedures such as, for example, a learning procedure, a simulation procedure, an artificial intelligence procedure, and/or an augmented intelligence procedure.

Identifying corners and edges in view of the example scenarios described above, is a second example challenge associated with generating a floorplan of the ground floor of the building 105, in addition to the first challenge described above with respect to recognizing that the surface 118 and the surface 117 belong to the wall 116 that is shared between the room 115 and the room 110.

Another challenge associated with generating a floorplan is determining characteristics of various elements such as, for example, a corner or a wall. In an example scenario, the wall 310 and/or the wall 116 may have a non-linear surface contour (curves, wall segments, protrusions, indentations, etc.). In another example scenario, the wall 310 may not be orthogonal to the wall 116 (and/or to the ceiling 335) at various places, including at the corner 315. Furthermore, the wall 310 may not run parallel to another wall (not shown) in the room 115. Accordingly, in accordance with the disclosure, the computer may evaluate a birds-eye view of the room 115 to determine various characteristics of corners and/or walls such as, for example, to determine whether the wall 310 runs parallel to the other wall. If not parallel, the computer generates a floorplan that indicates the characteristics of the wall 310 and also provides measurement values that can be used to determine separation distances between the wall 310 and the other wall at any desired location along the wall 310. In an example case, the computer may attach tags to various elements. The tags may be used to provide various types of information about the elements.

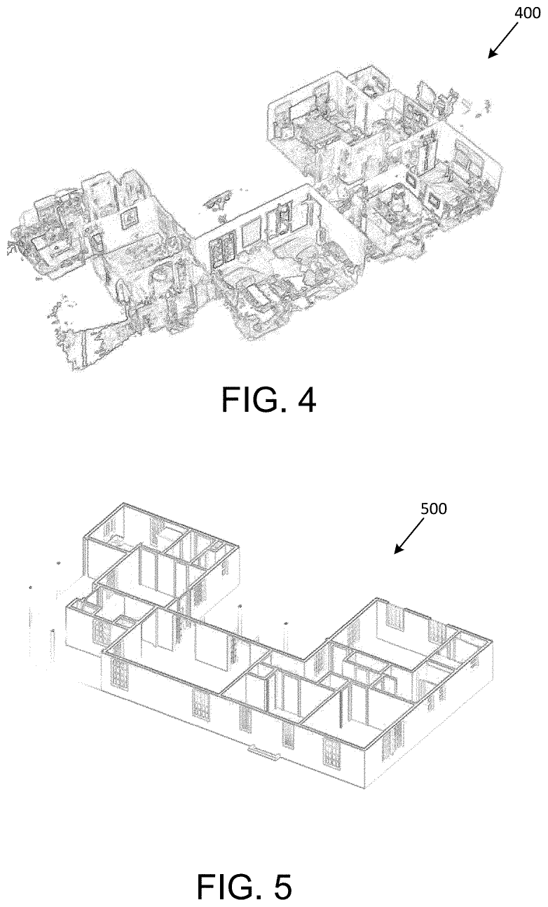

FIG. 4 illustrates an example framework 400 that may be operated upon by a computer (such as, for example, the computer 130) to generate a 3D rendering of a building. The building in this example, includes multiple rooms each of which can include various objects (furniture, wall fixtures, wall hangings, floor coverings, etc.) and structural elements (windows, doors, fireplace, walls, etc.). It is desirable to exclude the various objects (furniture, wall fixtures, wall hangings, floor coverings, etc.) in order to generate a floorplan of the floor of the building.

FIG. 5 illustrates an example 3D rendering 500 of the building that is shown in FIG. 4. The 3D rendering 500 may be generated by a computer such as, for example, the computer 130, by executing a software program that identifies and excludes various objects contained in the example framework 400 described above. Objects, particularly removable objects, are generally undesirable for inclusion in a floorplan because the floorplan is typically directed at providing information about structural details of the building. In an example implementation, the 3D rendering 500 can be generated in the form of a textured 3D rendering, using techniques such as, for example, artificial intelligence and/or augmented intelligence.

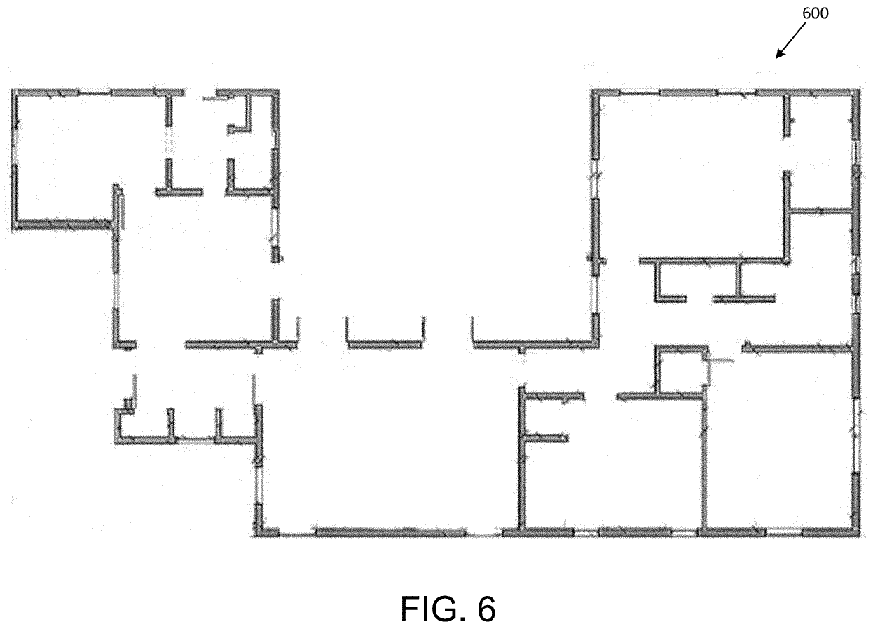

FIG. 6 illustrates a floorplan 600 of the floor of the building that is shown in FIG. 4. The floorplan 600 may be generated by a computer such as, for example, the computer 130, by executing a software program that converts the 3D rendering 500 into a birds-eye view of the building. Additional details pertaining to this procedure are provided below. The floorplan 600 includes various structural details of the building such as, for example, dimensions of various rooms (width, length, height, floor area, etc.), shapes of various rooms (rectangular, irregular, oval, etc.), dimensions and locations of doors and windows, and orientation (angular walls, curved walls).

In this example implementation, the floorplan 600 includes an entire floor of the building. In another implementation, the floorplan 600 can omit certain portions of the building such as, for example, several rooms other than a living room, for example. The floorplan of the living room may be used, for example, for purposes of renovating the living room.

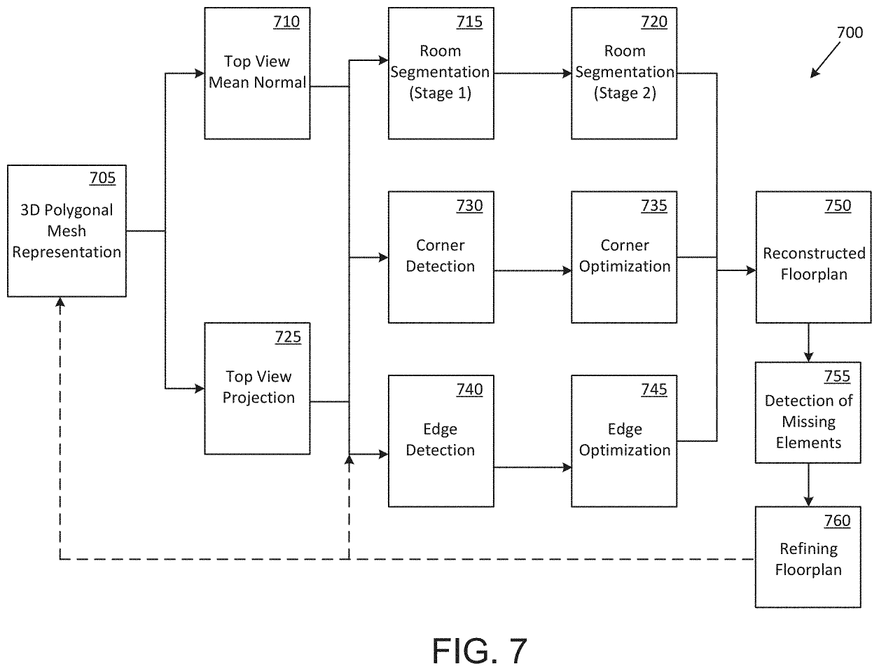

FIG. 7 shows a block diagram 700 of a method to generate a floorplan in accordance with an embodiment of the disclosure. The functional blocks shown in the block diagram 700 can be implemented by executing a software program in a computer, such as, for example, the computer 130. Block 705 pertains to a three-dimensional polygonal mesh representation that can be generated from an image captured by the personal device 120. In an example implementation, the image is a red-green-blue image (RGB image) having metadata associated with parameters such as, for example, distances, angles, scale, time, and camera settings. Distance parameters may be derived from information generated by a LiDAR device that can be a part of the personal device 120. The LiDAR device uses a laser beam to generate depth information and/or to generate distance information between a camera and imaging targets such as, for example, walls, doors, windows, etc. Camera settings information may be obtained from an inertial measurement unit (IMU).

In an example scenario, a series of synced RGB images may be obtained by executing a sequential image capture procedure (capturing images while walking from one room to another, for example). The synced RGB images, which can include depth information, can then be used to generate a three-dimensional polygonal mesh representation.

The three-dimensional polygonal mesh representation can be converted to a top view mean normal rendering (block 710) and a top view projection rendering (block 725). The top view mean normal rendering and/or the top view projection rendering can be operated upon for performing operations such as, for example, room segmentation (block 715 and block 720), corner detection (block 730), and edge detection (block 740).

Stage 1 of room segmentation (block 715) may involve segmenting the top view mean normal rendering and/or the top view projection rendering into individual rooms. The segmenting procedure may involve the use of procedures such as, for example, machine learning, density-based spatial clustering of applications (DBSCAN), and random sample consensus (RANSAC).

Stage 2 of room segmentation (block 720) may involve evaluating each room for identifying various structures (walls, doors, windows, etc.) that are actually present in the room, and to exclude non-existent elements that may be indicated in the three-dimensional polygonal mesh representation. In some cases, a non-existent element may be introduced into a three-dimensional polygonal mesh representation as a result of an erroneous interpretation of content present in an RGB image. In an example scenario, the non-existent element may be introduced into the three-dimensional polygonal mesh representation during image conversion during which, for example, a spot in an image may be erroneously interpreted as a corner, or a straight edge of a piece of furniture may be erroneously interpreted as an edge of a wall.

Distinguishing between structures that are actually present in a room versus non-existent elements (false positives) can be carried out in various ways. In one example approach, a processor can determine a likelihood of an existence of a structure in a room by applying a likelihood model (described below in further detail). In another example approach, a processor can determine a likelihood of an existence of a structure in a room by comparing the top view mean normal rendering and/or the top view projection rendering of the room to one or more template renderings. In an example procedure, a template rendering can be generated by executing a simulation procedure. In another example procedure, a template rendering can be a rendering corresponding to another building that is similar, or substantially identical, to the building from which the three-dimensional polygonal mesh representation of block 705 has been generated. The template renderings may be stored in a database of the computer 130 and/or in the cloud storage device 135.

Block 730 pertains to corner detection based on evaluating top view mean normal rendering and/or the top view projection rendering using techniques such as the ones described above with reference to block 720 (likelihood of existence, template renderings, etc.).

Block 740 pertains to edge detection based on evaluating top view mean normal rendering and/or the top view projection rendering using techniques such as the ones described above with reference to block 720 (likelihood of existence, template renderings, etc.).

Block 735 pertains to corner optimization where non-existent corners are excluded and a modified rendering is created. In an example operation, a non-existent corner of two walls may be excluded and replaced by a single wall.

Block 745 pertains to edge optimization where non-existent edges are excluded and a modified rendering is created. In an example operation, a non-existent edge on a wall may be excluded.

Block 750 pertains to producing a reconstructed floorplan based on operations indicated in block 720, block 735, and block 745. At block 755, various elements that may be missing in the reconstructed floorplan such as, for example, a wall or a corner, may be identified. In block 760, the reconstructed floorplan is refined based on actions indicated in block 755. In an example implementation, the reconstructed floorplan is refined by executing a software application that compares the reconstructed floorplan to one or more reference floorplans of other buildings. In at least some cases, a reference floorplan can be simulated floorplan of another building that may, or may not, be substantially similar to the building corresponding to the three-dimensional polygonal mesh representation indicated in block 705. The software application may execute some of such operations based on machine learning and neural networks.

In an example embodiment in accordance with disclosure, the reconstructed floorplan is refined by executing a manual interactive procedure. The manual interactive procedure may be executed by one or more individuals upon one or more devices. In an example scenario, the individual 125 may execute the manual interactive procedure upon the personal device 120. In another example scenario, an individual may execute the manual interactive procedure upon the computer 130. The manual interactive procedure is generally directed at manually modifying the reconstructed floorplan that has been generated automatically by a device such as, for example, the personal device 120 or the computer 130. A non-exhaustive list of modifications can include, for example, eliminating an object present in the reconstructed floorplan, modifying a measurement in the reconstructed floorplan, and/or introducing a measurement into the reconstructed floorplan.

Eliminating an object present in the reconstructed floorplan may be carried out, for example, by the individual examining the reconstructed floorplan, noticing the presence of an object that is undesirable for inclusion in a rendered floorplan (the sofa 330, for example), and eliminating the object from the reconstructed floorplan.

Modifying a measurement in the reconstructed floorplan may be carried out, for example, by the individual examining the reconstructed floorplan, noticing an erroneous measurement, performing a manual measurement operation (using a tape measure to measure a distance between two walls, for example), eliminating the erroneous measurement indicated in the reconstructed floorplan (or applying a strikethrough to the measurement indicated in the reconstructed floorplan), and inserting (or overwriting) the erroneous measurement with the measurement obtained via the manual measurement operation.

Introducing a measurement into the reconstructed floorplan may be carried out, for example, by the individual examining the reconstructed floorplan, noticing an omission of a measurement, performing a manual measurement operation (using a tape measure to measure a distance between two walls, for example), and inserting into the reconstructed floorplan, the measurement obtained via the manual measurement operation.

In another example scenario, the measurement indicated in the reconstructed floorplan can be an absolute value measurement and the insertion by the individual can provide an indication of a relative relationship. Thus, for example, an absolute value measurement may indicate a separation distance of 20 feet between a first wall and a second wall. The individual may provide an insertion such as, for example, “a separation distance between a first corner of the first wall and a first corner of the second wall is less than a separation distance between a second corner of the first wall and a second corner of the second wall.”

The refined floorplan may then be used for various purposes such as, for example, to produce a rendering of a floorplan (such as, for example, the floorplan 600 shown in FIG. 6) and/or to implement a procedure for refining some operations indicated in the block diagram 700. The refining can include, for example, modifying some actions associated with operating upon the three-dimensional polygonal mesh representation indicated in block 705 and/or modifying some actions indicated in block 715, block 730, and/or block 740.

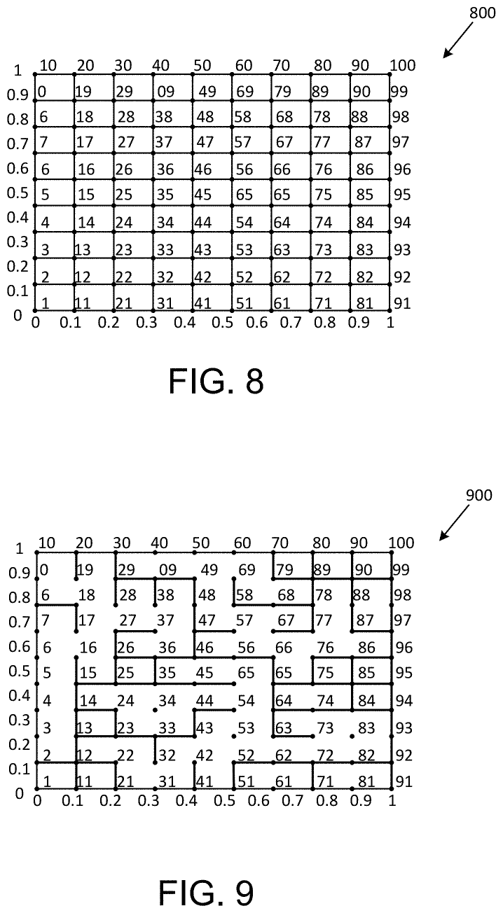

FIG. 8 illustrates a first example cross-sectional view of a three-dimensional polygonal mesh representation 800 that may be used for generating a floorplan in accordance with the disclosure. In an example implementation, the cross-sectional view may correspond to a desired height with respect to ground level, such as, for example, a cross-sectional view at a two-thirds height of a building. The three-dimensional polygonal mesh representation 800, which conforms to a Manhattan layout, is a point cloud representation that provides a birds-eye view of a building (or a portion of a building). The point cloud representation includes points corresponding to corners where walls meet (such as, for example, the corner 325 shown in FIG. 3). The Manhattan layout can be used to generate a floorplan of a building that generally conforms to a grid pattern. The building may include rooms conforming to square shapes and rectangular shapes.

The three-dimensional polygonal mesh representation 800 includes several lines and points corresponding to corners and walls that may, or may not, exist in a building. A computer, such as, for example, the computer 130, can generate a floorplan by operating upon the three-dimensional polygonal mesh representation 800 in the manner described above with respect to FIG. 7 (corner detection, edge detection, corner optimization, edge optimization, etc.).

FIG. 9 illustrates a second example cross-sectional view of a three-dimensional polygonal mesh representation 900. The three-dimensional polygonal mesh representation 900 may be generated by a computer, based on identifying non-existent edges in the three-dimensional polygonal mesh representation 800. Identifying non-existent edges may be performed by use of likelihood parameters and execution of procedures such as, for example, a learning procedure, a simulation procedure, an artificial intelligence procedure, and/or an augmented intelligence procedure. Several non-existent edges have been excluded in the three-dimensional polygonal mesh representation 900 based on identifying and removing these edges from the three-dimensional polygonal mesh representation 800.

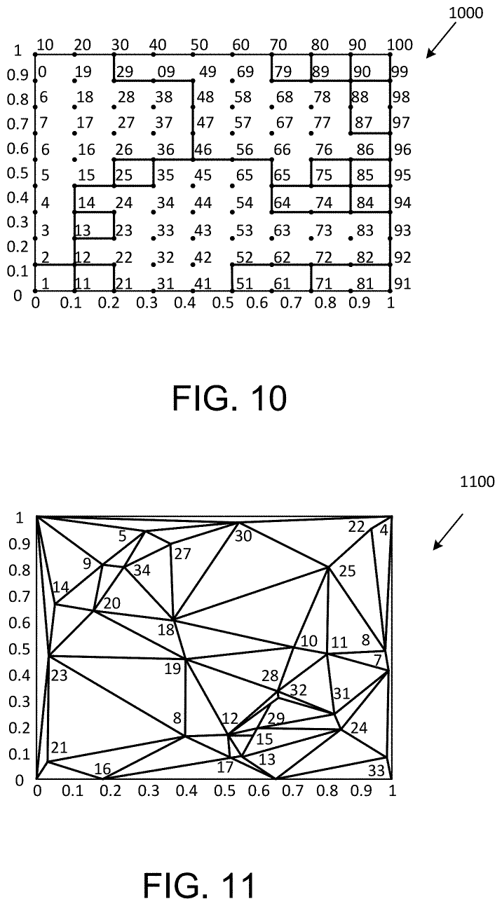

FIG. 10 illustrates a third example cross-sectional view of a three-dimensional polygonal mesh representation 1000. The three-dimensional polygonal mesh representation 1000 may be generated by a computer, based on evaluating the three-dimensional polygonal mesh representation 900 and performing operations such as, for example, combining two or more edges. The edges may be combined by use of likelihood parameters and execution of procedures such as, for example, a learning procedure, a simulation procedure, an artificial intelligence procedure, and/or an augmented intelligence procedure.

FIG. 11 illustrates a fourth example cross-sectional view of a three-dimensional polygonal mesh representation 1100 that may be used for generating a floorplan in accordance with the disclosure. The three-dimensional polygonal mesh representation 1100, which conforms to a layout other than a Manhattan layout (a non-Manhattan layout), is a point cloud representation that provides a birds-eye view of a building (or a portion of a building). The non-Manhattan layout can be used to generate a floorplan of a structure that includes rooms conforming to various polygonal shapes. In accordance with an embodiment of the disclosure, a floorplan of a building can be generated by use of a three-dimensional polygonal mesh representation that includes a Manhattan layout and a non-Manhattan layout. The combinational layout allows for representation of rooms having quadrilateral shapes, polygonal shapes, and/or various other irregular shapes. In some cases, the three-dimensional polygonal mesh representation can be a random mesh that includes a Manhattan layout, a non-Manhattan layout, and/or variants of such layouts.

The three-dimensional polygonal mesh representation 1100 includes several lines and points corresponding to corners and walls that may, or may not, exist in a building. A computer, such as, for example, the computer 130 can generate a floorplan by operating upon the three-dimensional polygonal mesh representation 1100 in the manner described above with respect to FIG. 7 (corner detection, edge detection, corner optimization, edge optimization, etc.).

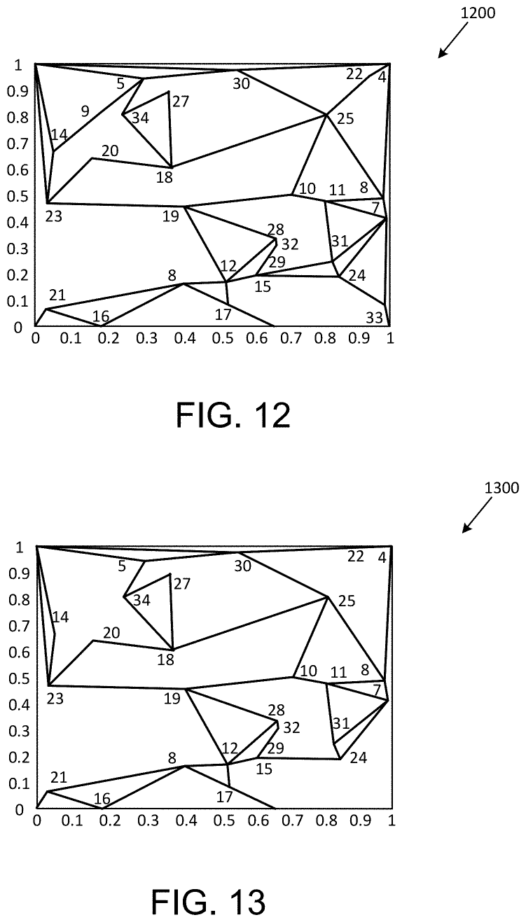

FIG. 12 illustrates a fifth example cross-sectional view of a three-dimensional polygonal mesh representation 1200. The three-dimensional polygonal mesh representation 1200 may be generated by a computer, based on identifying non-existent edges in the three-dimensional polygonal mesh representation 1100. Identifying non-existent edges may be performed by use of likelihood parameters and execution of procedures such as, for example, a learning procedure, a simulation procedure, an artificial intelligence procedure, and/or an augmented intelligence procedure. Several non-existent edges have been excluded in the three-dimensional polygonal mesh representation 900 based on identifying and removing these edges from the three-dimensional polygonal mesh representation 800.

FIG. 13 illustrates a sixth example cross-sectional view of a three-dimensional polygonal mesh representation 1300. The three-dimensional polygonal mesh representation 1300 may be generated by a computer, based on evaluating the three-dimensional polygonal mesh representation 1200 and performing operations such as, for example, combining two or more edges. The edges may be combined by use of likelihood parameters and execution of procedures such as, for example, a learning procedure, a simulation procedure, an artificial intelligence procedure, and/or an augmented intelligence procedure.

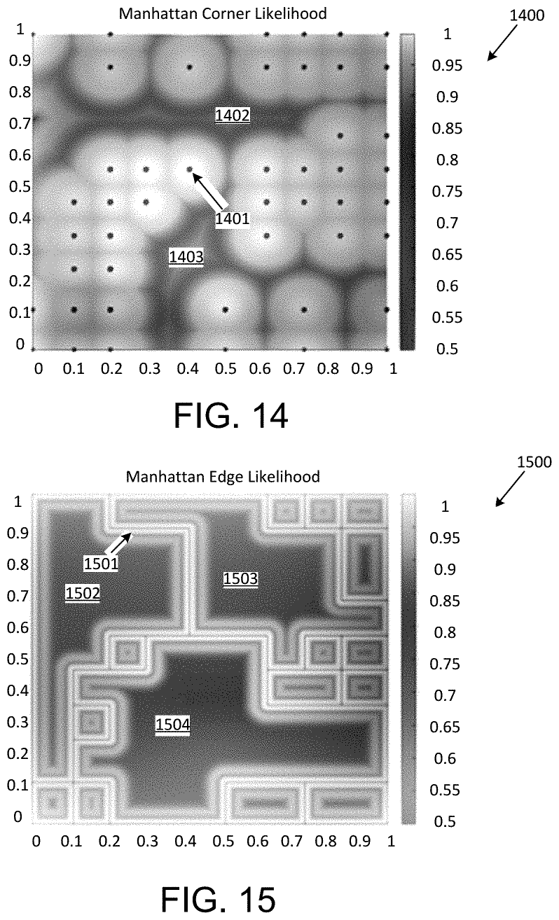

FIG. 14 shows a likelihood diagram 1400 that illustrates the likelihood of various corners being present in a Manhattan layout. Each of the dots provides an indication of a likelihood of an existence of a corner. More particularly, a dot 1401 (for example) provides an indication of a higher likelihood of a corner being present, than, for example, a corner being present in an area 1402 or an area 1403. In this example likelihood diagram 1400, the various corners correspond to the corners illustrated in the three-dimensional polygonal mesh representation 1000 shown in FIG. 10. In an example implementation, the likelihood diagram 1400 shown in FIG. 14 may be generated by associating likelihood parameters to each corner that is present in the three-dimensional polygonal mesh representation 1000 (shown in FIG. 10). A color scheme may be used to indicate various levels of likelihood.

FIG. 15 shows a likelihood diagram 1500 that illustrates the likelihood of various edges being present in a Manhattan layout. Each of the lines represents an edge. An intensity level of the shading straddling each line (edge) represents a likelihood of an existence of the edge. More particularly, a line 1501 (for example) provides an indication of a higher likelihood of an edge being present than, for example, an edge being present in an area 1502, an area 1503, and an area 1504. In the example likelihood diagram 1500, the various edges correspond to the edges illustrated in the three-dimensional polygonal mesh representation 1000 shown in FIG. 10. In an example implementation, the likelihood diagram 1500 shown in FIG. 15 may be generated by associating likelihood parameters to each edge that is present in the three-dimensional polygonal mesh representation 1000 (shown in FIG. 10). A color scheme may be used to indicate various levels of likelihood.

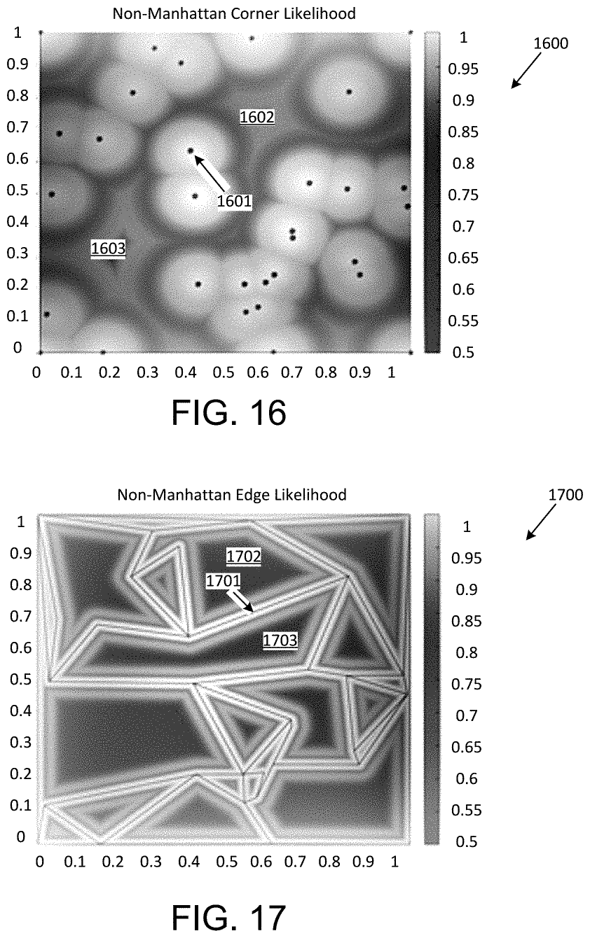

FIG. 16 shows a likelihood diagram 1600 that illustrates the likelihood of various corners being present in a non-Manhattan layout. Each of the black dots represents a corner. Each of the dots provides an indication of a likelihood of an existence of a corner. More particularly, a dot 1601 (for example) provides an indication of a higher likelihood of a corner being present, than, for example, a corner being present in an area 1602 or an area 1603. In this example likelihood diagram 1600, the various corners correspond to the corners illustrated in the three-dimensional polygonal mesh representation 1300 shown in FIG. 13. In an example implementation, the likelihood diagram 1600 shown in FIG. 16 may be generated by associating likelihood parameters to each corner that is present in the three-dimensional polygonal mesh representation 1300 (shown in FIG. 13). A color scheme may be used to indicate various levels of likelihood.

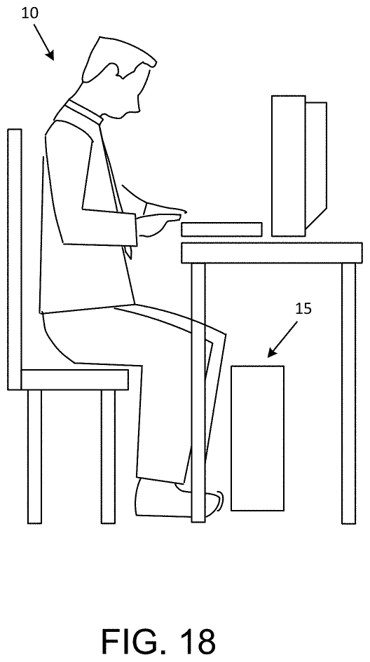

FIG. 17 shows a likelihood diagram 1700 that illustrates the likelihood of various edges being present in a non-Manhattan layout. Each of the lines represents an edge. An intensity level of the shading straddling each line (edge) represents a likelihood of an existence of the edge. More particularly, a line 1701 (for example) provides an indication of a higher likelihood of an edge being present than, for example, an edge being present in an area 1702 and an area 1703. In the example likelihood diagram 1700, the various edges correspond to the edges illustrated in the three-dimensional polygonal mesh representation 1300 shown in FIG. 13. In an example implementation, the likelihood diagram 1700 shown in FIG. 17 may be generated by associating likelihood parameters to each edge that is present in the three-dimensional polygonal mesh representation 1300 (shown in FIG. 13). A color scheme may be used to indicate various levels of likelihood.

With reference to FIG. 14 and FIG. 16, associating likelihood parameters to corners of a three-dimensional polygonal mesh representation can include simulating likelihood functions. This procedure can be carried out by evaluating each pixel of an image to determine a likelihood of the pixel being a part of a corner.

In an example implementation, the likelihood of the pixel being a part of a corner is modeled by a corner likelihood model that may be characterized by the following function:

G(x, C)=ϕ_{c}(∥x−xᵢ∥), where C: corner set

Function ϕ(r) can be any artificial function in R⁺→R, such that ϕ(0)=1, ϕ(∞)=0.

With reference to FIG. 15 and FIG. 17, associating likelihood parameters to edges of a three-dimensional polygonal mesh representation can include simulating likelihood functions. This procedure can be carried out by evaluating each pixel of an image to determine a likelihood of the pixel being a part of an edge.

In an example implementation, the likelihood of the pixel being a part of an edge is modeled by an edge likelihood model that may be characterized by the following function:

H(x,C)=ϕₑ(Dist(x,e)), E: edge set

Dist(x,e)=argmin_{y∈e}(∥x−y∥)

FIG. 18 illustrates an individual 10 executing a floorplan generation procedure upon a computer 15 in accordance with an embodiment of the disclosure. In this example scenario, the computer 15 is configured to operate as a floorplan generating device. More particularly, the computer 15 includes a processor and a memory containing computer-executable instructions. The processor is configured to access the memory and execute the computer-executable instructions to perform operations associated with floorplan generation in accordance with the disclosure.

A first example floorplan generation procedure that generally conforms to the block diagram illustrated in FIG. 7 is executed as a manual operation upon the computer 15. The manual operation may include actions performed by the individual 10 upon RGB images and/or upon a three-dimensional polygonal mesh representation that is communicated to the computer 15 from an image capture device (such as, for example, the personal device 120).

Some example actions can include room segmentation, corner detection and edge detection. In this scenario, the individual 10 may visually inspect an RGB image and/or a three-dimensional polygonal mesh representation of the RGB image to identify various rooms in a building and segment the three-dimensional polygonal mesh representation into the various rooms. The individual 10 may further identify objects (such as furniture, wall fixtures, wall hangings, floor coverings, etc.) and structural elements (walls, corners, ceiling, floor, doors, windows, etc.) of the room 115. The objects may be annotated and/or excluded for the purpose of generating the floorplan of the building.

The actions performed by the individual 10 may be configured to operate as a mentoring tool for teaching the processor to subsequently perform such actions autonomously. An artificial intelligence tool provided in the computer 15 (in the form of a software program, for example) may employ techniques such as machine-learning and artificial intelligence to learn the actions performed by the individual 10.

A second example floorplan generation procedure that generally conforms to the block diagram illustrated in FIG. 7 is executed as a semi-manual operation upon the computer 15. The semi-manual operation may include actions performed by the computer 15 that are monitored, corrected, and modified, on an as-needed basis, by the individual 10. Complementing operations performed by the computer 15 (particularly operations involving machine learning and/or artificial intelligence techniques) with manual guidance, may be referred to as augmented intelligence.

A third example floorplan generation procedure that generally conforms to the block diagram illustrated in FIG. 7 is executed as a fully autonomous operation by the computer 15. The fully autonomous operation is generally executed in accordance with the disclosure and can, in one example implementation, involve the use of machine learning models such as, for example, a sequential model that performs room segmentation procedures and a graph-based model that identifies relationships between various rooms.

In an example scenario, the third example floorplan generation procedure (and/or the second example floorplan generation procedure) autonomously identifies the wall 116 (shown in FIG. 1) as a shared wall that is shared between the room 115 and the room 110.

Furthermore, in some scenarios, the third example floorplan generation procedure (and/or the second floorplan generation procedure) may generate some room properties through room sequence prediction using a sequence model. The sequence model may be applied to one or more rooms. It may be desirable to generate two sets of room data in order to obtain information on individual rooms as well to identify how two or more rooms are interconnected.

Converting template floorplans into graphs and using a model that represents graph learning, is one example process to obtain information on how the rooms are interconnected with each other. In an example approach, each room is assumed to be a node and shared walls are assumed as edges. Since graphs do not show a special relationship across rooms, each room may be assigned coordinates in a coordinate plane. For doing so, a graph-to-image algorithm converts a graph of a floorplan to a list of coordinate points, one for each room.

The conversion procedure is carried out under the assumption that the floorplan is autonomously generated by the computer 15. In this case, the computer 15 is configured to operate as a simulation engine (with mentorship by the individual 10 who can intervene to choose which rooms the model creates and to autonomously collect the room data). The simulation engine can also be used to generate a randomized dataset that may be used for providing a machine learning framework on various computers.

The process of generating a floorplan from red-green-blue-depth (RGBD) information may be broadly defined by three steps. A first step pertains to image capture, where an image capture device such as, for example, the personal device 120, is operated to capture a set of RGB images while an individual such as, for example, the individual 125, walks from one room to another room of a building. Distance information associated with each RGB image may be obtained by use of a sensor such as, for example, time-of-flight (ToF) sensor. Time-related information may be obtained for example, by way of time-stamps generated by the image capture device and attached to captured images during image capture when the individual walks from one room to another.

In one scenario, a software application provided in the personal device 120 generates a floorplan based on the captured information. In another scenario, the captured information is propagated to a cloud-based device (the computer 130, for example) that generates a floorplan based on the captured information. Some aspects pertaining to generation of a floorplan have been described above. Additional aspects pertaining to generating a floorplan can include use of the time-related information (which may also be considered as odometry information). The odometry information is obtained from successive frames of an RGB image and used to generate a pose graph. The pose graph may be optimized to estimate a trajectory of motion of the image capture device and/or to determine camera pose. 3D point cloud fragments may be formed by projecting 2D pixels into a 3D space. A global pose graph may then be generated by matching corresponding features in various 3D fragments and by use of a feedback generation procedure. The global pose graph may be used for executing a floorplan estimation procedure. The floorplan estimation procedure can include an optimization pipeline to fit alpha shapes (linear simple curves that can be used for shape reconstruction) with a deep learning pipeline to predict the best-fit corners of each room point cloud. As a result, polygons that best describe each of the rooms present in the global point cloud are estimated. Finally, these polygons are stitched together by referring to the global point cloud and can be used as a usable 2D floor map of a room or a set of rooms.

One of the challenges in obtaining a room layout of an industrial building or a commercial building pertains to a size of such buildings. In such cases, a scalable solution may be applied that includes the use of multiple devices (image capture device, sensor devices etc.) rather than a single device, and infrastructure elements that support such devices (such as, for example, a 5G network). A scalable solution may further involve, for example, a fog-computing paradigm, fast data acquisition, and processing by leveraging distributed processing techniques in which multiple agents are used for mapping different parts of a building. The various images and/or three-dimensional polygonal mesh representations of various areas of a building may then be operated upon in a collective manner to generate a comprehensive floorplan of the entire building.

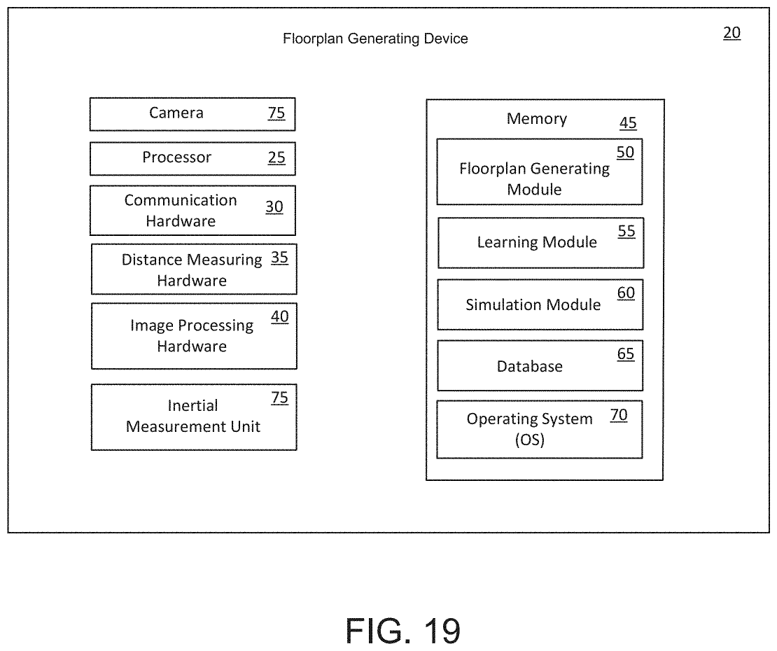

FIG. 19 shows some example components that may be provided in a floorplan generating device 20 in accordance with an embodiment of the disclosure. The floorplan generating device 20 can be implemented in various forms such as, for example, the personal device 120, the computer 130, or the computer 140 described above. Generally, in terms of hardware architecture, the floorplan generating device 20 can include a camera 75, a processor 25, communication hardware 30, distance measuring hardware 35, image processing hardware 40, an inertial measurement unit (IMU) 75, and a memory 45. In various other implementations, components such as, for example, a gyroscope and a flash unit can be included in the floorplan generating device 20. The various components may be communicatively coupled to each other via an interface (not shown). The interface can be, for example, one or more buses or other wired or wireless connections.

The communication hardware 30 can include a receiver and a transmitter (or a transceiver) configured to support communications between the floorplan generating device 20 and other devices such as, for example, the cloud storage device 135. The distance measuring hardware 35 can include, for example, a time-of-flight (ToF) system that may use a laser beam to determine a distance between the floorplan generating device 20 (when the floorplan generating device 20 is the personal device 120, for example) and an object or structure in a room, when the floorplan generating device 20 is used to capture images of the object or structure.

The image processing hardware 40 can include a graphics processing unit (GPU) configured to process images captured by the camera 75 of the floorplan generating device 20. The images may be captured by use of the camera 75 in the floorplan generating device 20 (when the floorplan generating device 20 is the personal device 120, for example) or may be loaded into the floorplan generating device 20 from another device (when the floorplan generating device 20 is the computer 130 or the computer 140).

The processor 25 is configured to execute a software application stored in the memory 45 in the form of computer-executable instructions. The processor 25 can be any custom made or commercially available processor, a central processing unit (CPU), an auxiliary processor among several processors associated with the floorplan generating device 20, a semiconductor-based microprocessor (in the form of a microchip or chip set), a macroprocessor, or generally any device for executing software instructions.

The memory 45, which is one example of a non-transitory computer-readable storage medium, may be used to store an operating system (OS) 70, a database 65, and code modules such as a floorplan generating module 50, a learning module 55, and a simulation module 60. The database 65 may be used to store items such as RGBD images and/or floorplans of various buildings.

The code modules are provided in the form of computer-executable instructions that can be executed by the processor 25 for performing various operations in accordance with the disclosure. In an example embodiment where the floorplan generating device 20 is the personal device 120, some or all of the code modules may be downloaded into the floorplan generating device 20 from the computer 130 or the cloud storage device 135.

More particularly, the floorplan generating module 50 can be executed by the processor 25 for performing some or all operations associated with the functional blocks shown in FIG. 7. The processor 25 may execute the learning module 55 for executing the various learning procedures described above. The processor 25 may execute the simulation module 60 for executing the various simulation procedures described above.

The memory 45 can include any one or a combination of volatile memory elements (e.g., random access memory (RAM, such as DRAM, SRAM, SDRAM, etc.)) and nonvolatile memory elements (e.g., ROM, hard drive, tape, CDROM, etc.). Moreover, the memory 45 may incorporate electronic, magnetic, optical, and/or other types of storage media. Note that the memory 45 can have a distributed architecture, where various components are situated remote from one another, but can be accessed by the processor 25.

The operating system 70 essentially controls the execution of various software programs in the floorplan generating device 20, and provides services such as scheduling, input-output control, file and data management, memory management, and communication control.

Some or all of the code modules may be provided in the form of a source program, an executable program (object code), a script, or any other entity comprising a set of instructions to be performed. When a source program, the program may be translated via a compiler, assembler, interpreter, or the like, which may or may not be included within the memory 45, so as to operate properly in connection with the O/S 70. Furthermore, some or all of the code modules may be written as (a) an object-oriented programming language, which has classes of data and methods, or (b) a procedure programming language, which has routines, subroutines, and/or functions, for example but not limited to, C, C++, Pascal, Basic, Fortran, Cobol, Perl, Java, and Ada.

In some cases, where the floorplan generating device 20 is a laptop computer, desktop computer, workstation, or the like, the software in the memory 45 may further include a basic input output system (BIOS) (omitted for simplicity). The BIOS is a set of essential software routines that initialize and test hardware at startup, start the O/S 70, and support the transfer of data among various hardware components. The BIOS is stored in ROM so that the BIOS can be executed when the floorplan generating device 20 is powered up.

The implementations of this disclosure can correspond to methods, apparatuses, systems, non-transitory computer readable media, devices, and the like for generating a floorplan of a building. In some implementations, a method comprises generating a three-dimensional polygonal mesh representation of at least a portion of a first building; identifying, in the three-dimensional polygonal mesh representation, a first room; determining an authenticity of an element indicated in the three-dimensional polygonal mesh representation; and one of including a structure or excluding the structure in a rendering of the first room, based on the authenticity of the element indicated in the three-dimensional polygonal mesh representation.

In some implementations of the method, the element indicated in the three-dimensional polygonal mesh representation corresponds to one of an edge or a corner of the first room, and wherein the structure is a first wall associated with the one of the edge or the corner of the first room.

In some implementations, the method further comprises identifying, in the three-dimensional polygonal mesh representation, a second room; identifying, in the three-dimensional polygonal mesh representation, a second wall in the second room; and determining that the second wall in the second room is the same as the first wall in the first room.

In some implementations of the method, the rendering of the first room is one of a floorplan of the at least the portion of the first building or a three-dimensional drawing of the at least the portion of the first building.

In some implementations of the method, determining the authenticity of the element indicated in the three-dimensional polygonal mesh representation comprises at least one of executing a corner likelihood procedure, executing an edge likelihood procedure, or executing a simulation procedure.

In some implementations of the method, determining the authenticity of the element indicated in the three-dimensional polygonal mesh representation comprises executing at least one of a learning procedure, an artificial intelligence procedure, or an augmented intelligence procedure.

In some implementations, a method comprises generating a three-dimensional polygonal mesh representation of at least a portion of a first building; generating a reconstructed floorplan by operating upon the three-dimensional polygonal mesh representation; refining the reconstructed floorplan by comparing the reconstructed floorplan to a reference floorplan of at least a portion of a second building; and producing a rendered floorplan based on refining the reconstructed floorplan.

In some implementations of the method, the reference floorplan is a simulated floorplan.

In some implementations of the method, refining the reconstructed floorplan comprises executing at least one of a simulation procedure, a learning procedure, an artificial intelligence procedure, or an augmented intelligence procedure.

In some implementations of the method, the second building is substantially similar to the first building.

In some implementations, the method further comprises evaluating the three-dimensional polygonal mesh representation to determine an authenticity of an element included in the three-dimensional polygonal mesh representation; and excluding a structure in the reconstructed floorplan, based on determining a lack of authenticity of the element included in the three-dimensional polygonal mesh representation.

In some implementations of the method, the element included in the three-dimensional polygonal mesh representation is one of an edge or a corner, and wherein the structure is a first wall in a first room.

In some implementations, the method further comprises evaluating the three-dimensional polygonal mesh representation to identify a second room in the at least the portion of the first building; identifying a second wall in the second room; and determining that the second wall in the second room is same as the first wall in the first room.

In some implementations, a system includes a floorplan generating device comprising a first memory that stores computer-executable instructions; and a first processor configured to access the first memory and execute the computer-executable instructions to at least generate a three-dimensional polygonal mesh representation of at least a portion of a first building; identify, in the three-dimensional polygonal mesh representation, a first room; determine an authenticity of an element indicated in the three-dimensional polygonal mesh representation corresponding to the first room; and one of include a structure or exclude the structure in a rendering of the first room, based on the authenticity of the element indicated in the three-dimensional polygonal mesh representation.

In some implementations of the system, the three-dimensional polygonal mesh representation comprises a Manhattan style configuration and a non-Manhattan style configuration, and wherein the at least the portion of the first building is a floor of one of a single-story building or a multi-storied building.

In some implementations of the system, the floorplan generating device is one of a personal device or a cloud computer, and wherein the computer-executable instructions are included in a downloadable software application.

In some implementations of the system, the downloadable software application is executable to implement at least one of a simulation procedure, a learning procedure, an artificial intelligence procedure, or an augmented intelligence procedure.

In some implementations of the system, the floorplan generating device is a cloud computer, and the system further comprises a personal device. The personal device comprises a second memory that stores computer-executable instructions; and a second processor configured to access the second memory and execute the computer-executable instructions to at least capture a first image of the first room in the at least the portion of the first building; capture a second image of a second room in the at least the portion of the first building; generate, based in part on the first image and the second image, the three-dimensional polygonal mesh representation; and upload the three-dimensional polygonal mesh representation to the cloud computer, for generating a floorplan of the at least the portion of the first building.

In some implementations of the system, the structure is a wall of the first room and the first processor is further configured to access the first memory and execute additional computer-executable instructions to at least identify a second room in the at least the portion of the first building based on evaluating the three-dimensional polygonal mesh representation; and determine that the wall of the first room is a shared wall that is shared between the first room and the second room.

In some implementations of the system, the structure is a wall of the first room and the first processor is further configured to access the first memory and execute additional computer-executable instructions to at least determine the authenticity of the element indicated in the three-dimensional polygonal mesh representation based on comparing a reconstructed floorplan of the at least the portion of the first building to a reference floorplan of at least a portion of a second building.

The implementations of this disclosure can be described in terms of functional block components and various processing operations. Such functional block components can be realized by a number of hardware or software components that perform the specified functions. For example, the disclosed implementations can employ various integrated circuit components (e.g., memory elements, processing elements, logic elements, look-up tables, and the like), which can carry out a variety of functions under the control of one or more microprocessors or other control devices. Similarly, where the elements of the disclosed implementations are implemented using software programming or software elements, the systems and techniques can be implemented with a programming or scripting language, such as C, C++, Java, JavaScript, assembler, or the like, with the various algorithms being implemented with a combination of data structures, objects, processes, routines, or other programming elements.

Functional aspects can be implemented in algorithms that execute on one or more processors. Furthermore, the implementations of the systems and techniques disclosed herein could employ a number of conventional techniques for electronics configuration, signal processing or control, data processing, and the like. The words “mechanism” and component” are used broadly and are not limited to mechanical or physical implementations, but can include software routines in conjunction with processors, etc. Likewise, the terms “system” or “tool” as used herein and in the figures, but in any event based on their context, may be understood as corresponding to a functional unit implemented using software, hardware (e.g., an integrated circuit, such as an ASIC), or a combination of software and hardware. In certain contexts, such systems or mechanisms may be understood to be a processor-implemented software system or processor-implemented software mechanism that is part of or callable by an executable program, which may itself be wholly or partly composed of such linked systems or mechanisms.

Implementations or portions of implementations of the above disclosure can take the form of a computer program product accessible from, for example, a computer-usable or computer-readable medium. A computer-usable or computer-readable medium can be a device that can, for example, tangibly contain, store, communicate, or transport a program or data structure for use by or in connection with a processor. The medium can be, for example, an electronic, magnetic, optical, electromagnetic, or semiconductor device.

Other suitable mediums are also available. Such computer-usable or computer-readable media can be referred to as non-transitory memory or media, and can include volatile memory or non-volatile memory that can change over time. The quality of memory or media being non-transitory refers to such memory or media storing data for some period of time or otherwise based on device power or a device power cycle. A memory of an apparatus described herein, unless otherwise specified, does not have to be physically contained by the apparatus, but is one that can be accessed remotely by the apparatus, and does not have to be contiguous with other memory that might be physically contained by the apparatus.

While the disclosure has been described in connection with certain implementations, it is to be understood that the disclosure is not to be limited to the disclosed implementations but, on the contrary, is intended to cover various modifications and equivalent arrangements included within the scope of the appended claims, which scope is to be accorded the broadest interpretation so as to encompass all such modifications and equivalent structures as is permitted under the law.

That which is claimed is:

1. A method comprising:
generating a three-dimensional polygonal mesh representation of at least a portion of a first building;
identifying, in the three-dimensional polygonal mesh representation, a first room;
determining an authenticity of an element indicated in the three-dimensional polygonal mesh representation; and
one of including a structure or excluding the structure in a rendering of the first room, based on the authenticity of the element indicated in the three-dimensional polygonal mesh representation.

2. The method of claim 1, wherein the element indicated in the three-dimensional polygonal mesh representation corresponds to one of an edge or a corner of the first room, and wherein the structure is a first wall associated with the one of the edge or the corner of the first room.

3. The method of claim 2, further comprising:
identifying, in the three-dimensional polygonal mesh representation, a second room;
identifying, in the three-dimensional polygonal mesh representation, a second wall in the second room; and
determining that the second wall in the second room is the same as the first wall in the first room.

4. The method of claim 2, wherein the rendering of the first room is one of a floorplan of the at least the portion of the first building or a three-dimensional drawing of the at least the portion of the first building.

5. The method of claim 2, wherein determining the authenticity of the element indicated in the three-dimensional polygonal mesh representation comprises at least one of executing a corner likelihood procedure, executing an edge likelihood procedure, or executing a simulation procedure.

6. The method of claim 2, determining the authenticity of the element indicated in the three-dimensional polygonal mesh representation comprises executing at least one of a learning procedure, an artificial intelligence procedure, or an augmented intelligence procedure.

7. A method executed by a processor, the method comprising:
generating a three-dimensional polygonal mesh representation of at least a portion of a first building;
generating a reconstructed floorplan by operating upon the three-dimensional polygonal mesh representation;
refining the reconstructed floorplan, the refining comprising comparing the reconstructed floorplan to a reference floorplan of at least a portion of a second building; and
producing a rendered floorplan based on refining the reconstructed floorplan.

8. The method of claim 7, wherein the reference floorplan is a simulated floorplan.

9. The method of claim 7, wherein refining the reconstructed floorplan comprises executing at least one of a simulation procedure, a learning procedure, an artificial intelligence procedure, or an augmented intelligence procedure.

10. The method of claim 7, wherein refining the reconstructed floorplan further comprises:
executing a manual interactive procedure that includes at least one of eliminating an object present in the reconstructed floorplan, modifying a first measurement in the reconstructed floorplan, and introducing a second measurement into the reconstructed floorplan.

11. The method of claim 7, wherein the method further comprises:
evaluating the three-dimensional polygonal mesh representation to determine an authenticity of an element included in the three-dimensional polygonal mesh representation; and
excluding a structure in the reconstructed floorplan, based on determining a lack of authenticity of the element included in the three-dimensional polygonal mesh representation.

12. The method of claim 11, wherein the element included in the three-dimensional polygonal mesh representation is one of an edge or a corner, and wherein the structure is a first wall in a first room.

13. The method of claim 12, further comprising:
evaluating the three-dimensional polygonal mesh representation to identify a second room in the at least the portion of the first building;
identifying a second wall in the second room; and
determining that the second wall in the second room is same as the first wall in the first room.

14. A system comprising:
a floorplan generating device comprising:
a first memory that stores computer-executable instructions; and
a first processor configured to access the first memory and execute the computer-executable instructions to at least:
generate a three-dimensional polygonal mesh representation of at least a portion of a first building;
identify, in the three-dimensional polygonal mesh representation, a first room;
determine an authenticity of an element indicated in the three-dimensional polygonal mesh representation corresponding to the first room; and
one of include a structure or exclude the structure in a rendering of the first room, based on the authenticity of the element indicated in the three-dimensional polygonal mesh representation.

15. The system of claim 14 wherein the three-dimensional polygonal mesh representation comprises a Manhattan style configuration and a non-Manhattan style configuration, and wherein the at least the portion of the first building is a floor of one of a single-story building or a multi-storied building.

16. The system of claim 14, wherein the floorplan generating device is one of a personal device or a cloud computer, and wherein the computer-executable instructions are included in a downloadable software application.

17. The system of claim 16, wherein the downloadable software application is executable to implement at least one of a simulation procedure, a learning procedure, an artificial intelligence procedure, or an augmented intelligence procedure.

18. The system of claim 14, wherein the floorplan generating device is a cloud computer, and wherein the system further comprises:
a personal device comprising:
a second memory that stores computer-executable instructions; and
a second processor configured to access the second memory and execute the computer-executable instructions to at least:
capture a first image of the first room in the at least the portion of the first building;
capture a second image of a second room in the at least the portion of the first building;
generate, based in part on the first image and the second image, the three-dimensional polygonal mesh representation; and
upload the three-dimensional polygonal mesh representation to the cloud computer, for generating a floorplan of the at least the portion of the first building.

19. The system of claim 14, wherein the structure is a wall of the first room and wherein the first processor is further configured to access the first memory and execute additional computer-executable instructions to at least:
identify a second room in the at least the portion of the first building based on evaluating the three-dimensional polygonal mesh representation; and
determine that the wall of the first room is a shared wall that is shared between the first room and the second room.

20. The system of claim 14, wherein the structure is a wall of the first room and wherein the first processor is further configured to access the first memory and execute additional computer-executable instructions to at least:
determine the authenticity of the element indicated in the three-dimensional polygonal mesh representation based on comparing a reconstructed floorplan of the at least the portion of the first building to a reference floorplan of at least a portion of a second building.
